(19) United States
(12) Patent Application Publication
(10) Pub. No.: US 2026/0173404 A1
(43) Pub. Date: Jun. 18, 2026

(54) SHARED CHANNEL-BASED ARTIFICIAL INTELLIGENCE NEUROMORPHIC DEVICE

(71) Applicant: POSTECH RESEARCH AND BUSINESS DEVELOPMENT FOUNDATION, Pohang-si (KR)

(72) Inventors: Seyoung KIM, Pohang-si (KR); Seungkun KIM, Daejeon (KR); Jinho BYUN, Pohang-si (KR)

(73) Assignee: POSTECH RESEARCH AND BUSINESS DEVELOPMENT FOUNDATION, Pohang-si (KR)

(21) Appl. No.: 19/415,555

(22) Filed: Dec. 10, 2025

(30) Foreign Application Priority Data
Dec. 12, 2024 (KR) 10-2024-0185097

(51) Int. Cl. H10B 63/00; G06N 3/065; H10N 70/20

(52) U.S. Cl. CPC H10B 63/30; G06N 3/065; H10B 63/80; H10N 70/253

(57) ABSTRACT

A shared channel-based artificial intelligence neuromorphic device includes a substrate, a shared channel layer stacked on the substrate, a source electrode at least partially overlapping one end of the shared channel layer, a drain electrode at least partially overlapping the other end of the shared channel layer, a shared gate dielectric stacked on the shared channel layer between the source electrode and the drain electrode on the substrate, a transistor stack including a first gate electrode, and a synapse stack including a second gate electrode. Each of the transistor stack and the synapse stack includes at least a portion of the shared channel layer and at least a portion of the shared gate dielectric so that the shared channel layer and the shared gate dielectric are shared by the transistor stack and the synapse stack.

### CROSS-REFERENCE TO RELATED APPLICATIONS

This application claims the benefit of and priority to Korean Patent Application No. 10-2024-0185097, filed on Dec. 12, 2024, the entire contents of which are incorporated herein by reference for all purposes.

### TECHNICAL FIELD

The present disclosure relates to a shared channel-based artificial intelligence neuromorphic device, and particularly to, for example, without limitation, a three-terminal analog memory device using a channel-boosting effect and a method of operating the same.

### BACKGROUND

Learning through artificial neural networks that mimic the brain's parallel computational processing is expected to achieve computational acceleration by hundreds to thousands of times compared to conventional digital hardware, as inference and training processes are performed via vector-matrix and outer-product operations. In particular, computational acceleration can be realized using a hardware cross-point array based on a variable resistance synapse device. Conventionally, an operating method for a cross-point based on a two-terminal analog synapse has been proposed.

The conventional driving method of the variable resistance synapse-based cross-point array for accelerating learning in artificial neural networks is limited to a two-terminal synapse device functioning as a variable resistance memory. Such a method deteriorates the performance of a three-terminal analog memory device and affects the stable operation of the array. Accordingly, a new unit synapse is required to improve the performance of a memory device and array having a three-terminal structure rather than a two-terminal one.

In order to perform learning of an artificial neural network using a cross-point based on a variable resistance synapse, a half-bias scheme is used, in which voltage pulses of opposite polarities, each having half a driving voltage amplitude, are applied to the gate and source directions of the cross-point so that the synapse device within the cross-point array is updated only when the pulses overlap. However, this may be applied only to the variable resistance array having the two-terminal structure. When the same method is applied to the variable resistance array having the three-terminal structure, sufficient updates will not occur even when pulse overlap takes place, which is due to a voltage drop within a channel layer resulting from the three-terminal structure. Therefore, the operational characteristics of the individual device and the array deteriorate.

The description of related art should not be considered prior art merely because it is mentioned in or associated with this section. The description of related art includes information that describes one or more aspects of the subject technology, and the description in this section does not limit the scope of the present disclosure.

### SUMMARY

One or more aspects of the present disclosure provide a shared channel-based artificial intelligence neuromorphic device, which can overcome and update degradation caused by a conventional voltage drop, by applying a unit cell structure in which a three-terminal analog memory device constituting a synapse is connected in series with a transistor, such that a uniform voltage is formed across the analog memory device through the channel-boosting effect of bias applied to a channel.

Further, one or more aspects of the present disclosure provide an artificial intelligence neuromorphic device, which can improve the learning accuracy of a hardware cross-point array that mimics an artificial neural network, by establishing a driving method for the cross-point array based on unit cells.

One or more aspects of the present disclosure provide a shared channel-based artificial intelligence neuromorphic device including a substrate, a shared channel layer stacked on the substrate, a shared gate dielectric stacked on the shared channel layer, a transistor stack including a first gate electrode, and a synapse stack including a second gate electrode. Each of the transistor stack and the synapse stack includes at least a portion of the shared channel layer and at least a portion of the shared gate dielectric so that the shared channel layer and the shared gate dielectric are shared by the transistor stack and the synapse stack.

The artificial intelligence neuromorphic device may further include a source electrode at least partially overlapping one end of the shared channel layer, and a drain electrode at least partially overlapping the other end of the shared channel layer.

The shared channel layer may be stacked within a cavity formed between the source electrode and the drain electrode.

The shared channel layer may extend toward lower inner sides facing each other from the source electrode and the drain electrode.

When the synapse stack is an electrochemical memory device, the synapse stack may further include a charge storage layer disposed above or beneath the shared gate dielectric.

When the charge storage layer is positioned beneath the shared gate dielectric, the shared gate dielectric may be disposed to form a step beneath the first and second gate electrodes.

The charge storage layer may be disposed above or beneath the shared gate dielectric to implement analog memory characteristics.

When the synapse stack is a flash-based memory device, a floating gate or a charge trapping layer may be stacked on the shared gate dielectric, and an insulating layer may be stacked on the floating gate or the charge trapping layer.

The shared channel layer located between the first gate electrode and the second gate electrode may be configured to have a negative threshold voltage.

For vector-matrix multiplication, the first gate electrode may be turned on and an input voltage may be applied to the source electrode to perform a forward pass operation for inference, and the first gate electrode may be turned on and a delta voltage may be applied to the drain electrode to perform a backward pass operation for error calculation.

For vector-vector outer product operation, the first gate electrode may be turned off, and probabilistic voltage pulses of opposite polarities may be applied to the second gate electrode and the source electrode.

One or more aspects of the present disclosure provide a shared channel-based artificial intelligence neuromorphic device, in which a cross-point array based on a resistive processing unit includes a unit cell composed of a transistor and a synapse device, and the unit cell is configured in a structure in which the transistor and the synapse device are connected in series.

The transistor may be composed of an n-type or p-type semiconductor, the transistor may include a metal-oxide-semiconductor field-effect transistor (MOSFET) or an oxide semiconductor, and the synapse device may include a three-terminal analog memory device.

For vector-matrix operation, the transistor may be turned on, and a current generated by resistance of the synapse device may be measured.

For weight updating, the transistor may be turned off, and voltage pulses may be applied to a gate electrode and a source electrode of the synapse device using a half-bias scheme.

The disclosed technology may provide the following effects. However, this does not mean that a particular embodiment must include all or only the following effects, and therefore, the scope of and rights in the disclosed technology should not be understood as being limited thereto.

The shared channel-based artificial intelligence neuromorphic device according to an example embodiment of the present disclosure can overcome and update degradation caused by a conventional voltage drop, by applying a unit cell structure in which a three-terminal analog memory device constituting a synapse is connected in series with a transistor, such that a uniform voltage is formed across the analog memory device through the channel-boosting effect of bias applied to a channel.

Further, the shared channel-based artificial intelligence neuromorphic device according to an example embodiment of the present disclosure can improve the learning accuracy of a hardware cross-point array that mimics an artificial neural network, by establishing a driving method for the cross-point array based on unit cells.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a diagram for explaining a shared channel-based artificial intelligence neuromorphic device according to an example embodiment of the present disclosure.

FIG. 2 is a sectional view for explaining the shared channel-based artificial intelligence neuromorphic device according to an example embodiment of the present disclosure.

FIGS. 3A to 3E are sectional views illustrating a method of manufacturing a shared channel-based artificial intelligence neuromorphic device according to an example embodiment of the present disclosure.

FIGS. 4 and 5 are sectional views illustrating a shared channel-based artificial intelligence neuromorphic device according to another example embodiment of the present disclosure.

FIGS. 6A and 6B are diagrams for explaining an operating method of a shared channel-based artificial intelligence neuromorphic device according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

The description of the present disclosure provides examples for structural and functional explanation, and therefore, the scope of the present disclosure should not be interpreted as being limited to embodiments described herein. That is, since the embodiments may be variously changed and take various forms, the scope of the present disclosure should be understood to include equivalents capable of realizing the technical spirit thereof. In addition, the objects or effects presented in the present disclosure do not mean that a particular embodiment must include all of them or only those effects, and therefore, the scope of the present disclosure should not be understood as being limited thereto.

Meanwhile, the meanings of the terms described herein should be understood as follows.

The terms “first,” “second,” etc. may be used merely to refer to one component separately from another component, and the scope of and rights in the present technology should not be limited by these terms. For instance, a first component could be termed a second component. Similarly, the second component could also be termed the first component.

It will be understood that when a component is referred to as being “connected” to another component, it can be directly connected to the other component or intervening components may be present therebetween. In contrast, it should be understood that when a component is referred to as being “directly connected” to another component, there are no intervening components present. Other expressions that explain the relationship between components, such as “between,” “directly between,” “adjacent to” or “directly adjacent to” should be construed in the same way.

In the present disclosure, the singular forms are intended to include the plural forms as well, unless the context clearly indicates otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise.

Further, unless stated otherwise, “at least some,” “some,” “at least some parts,” “at least a portion,” “at least a part,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, unless stated otherwise, “at least some,” “some,” “at least some parts,” “at least a portion,” “at least a part,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

It will be further understood that the terms “comprise,” “include,” “have,” etc. when used in this specification, specify the presence of stated features, integers, steps, operations, components, parts, or combinations thereof but do not preclude the presence or addition of one or more other features, integers, steps, operations, components, parts, or combinations thereof.

In the respective steps, reference symbols (e.g., a, b, c, etc.) are used merely for convenience of description, and such symbols do not indicate the order of the steps. Unless a specific order is explicitly stated in the context, the steps may occur in an order different from the stated order. That is, the steps may occur in the same order as described, may be performed substantially simultaneously, or may be carried out in the reverse order.

The present disclosure may be implemented as code readable by a computer stored on a computer-readable recording medium, and the computer-readable recording medium includes all types of recording devices in which data readable by a computer system is stored. Examples of the computer-readable recording medium include ROM, RAM, CD-ROM, magnetic tape, floppy disk, and optical data storage devices. In addition, the computer-readable recording medium may be distributed across computer systems connected through a network, allowing the computer-readable code to be stored and executed in a distributed manner.

Unless otherwise defined, all terms used herein have the same meaning as commonly understood by one of ordinary skill in the art to which the present disclosure belongs. It will be further understood that terms defined in commonly used dictionaries should be interpreted as having a meaning that is consistent with their meaning in the context of the relevant art and will not be interpreted in an idealized or overly formal sense unless expressly so defined herein.

Hereinafter, example embodiments of the present disclosure will be described in detail with reference to the accompanying drawings. The same reference numerals are used throughout the drawings to designate the same or similar components, and duplicate descriptions for identical components are omitted.

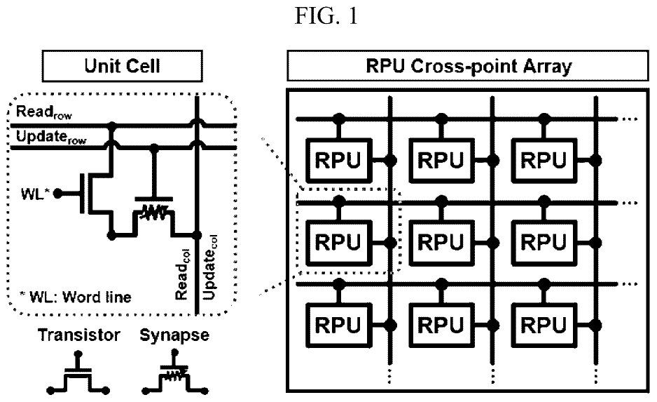

FIG. 1 is a diagram for explaining a shared channel-based artificial intelligence neuromorphic device according to an example embodiment of the present disclosure, illustrating a unit cell constituting a cross-point array based on a resistive processing unit (RPU).

Referring to FIG. 1, the unit cell of the cross-point array based on the resistive processing unit may be configured in a structure in which a transistor and a synapse device are connected in series. In an example, a resistive processing unit may include a resistor or a device that exhibits characteristics of a resistor.

In one embodiment, one end of the transistor and one end of the synapse device are connected in series, a gate of the transistor is connected to a word line, and the other end of the transistor is connected to a read line. A gate of the synapse device is connected to an update line, and the other end of the synapse device is connected to the read line. The update line may deliver a signal for adjusting a weight of the synapse, while the read line may deliver a signal for reading the current state or output value of the synapse.

In one embodiment, both n-type and p-type transistors may be used as the transistor constituting the unit cell, and various types of transistors such as MOSFETs and oxide semiconductors may be employed. Meanwhile, any three-terminal device having analog memory characteristics may be utilized as the synapse device constituting the unit cell.

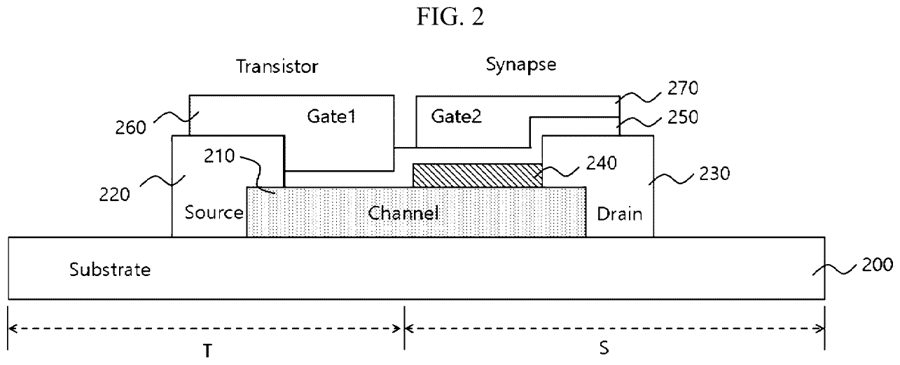

FIG. 2 is a sectional view for explaining a shared channel-based artificial intelligence neuromorphic device according to an example embodiment of the present disclosure, illustrating a cross-section of a unit cell including a transistor region T and a synapse device region S.

Referring to FIG. 2, the unit cell of the shared channel-based artificial intelligence neuromorphic device is configured to share a shared channel layer 210, in which two gates 260 and 270 of a single device are separately formed and arranged.

In one embodiment, the transistor and the synapse device are connected in series, and more specifically, the transistor and the synapse device may be physically connected in series through metal. At this time, any type of transistor may be used for the transistor, and any three-terminal device having analog memory characteristics may be utilized for the synapse device.

In one embodiment, the transistor region T and the synapse device region S may be configured as a transistor stack and a synapse stack that share a shared channel layer 210. The transistor stack and the synapse stack may share the channel layer in a compatible manner, and may include different gate electrodes.

The transistor stack and the synapse stack may be compatible with each other in several ways. For example, these stacks may have electrical compatibility (for example, compatible voltage levels and current ratings) that allows them to operate together without causing electrical problems. Additionally, these stacks may have functional compatibility that allows them to operate together without causing functional problems. Furthermore, these stacks may have technology compatibility that allows them to be fabricated using the same fabrication process.

First, the transistor stack of the shared channel-based artificial intelligence neuromorphic device may include a substrate 200, a shared channel layer 210 stacked on the substrate 200, a shared gate dielectric 250 formed on the shared channel layer 210, and a first gate electrode 260. In addition, the synapse stack of the shared channel-based artificial intelligence neuromorphic device may include the substrate 200, the shared channel layer 210 stacked on the substrate 200, an electrolyte 240 formed on the shared channel layer 210, the shared gate dielectric 250 formed on the electrolyte 240, and a second gate electrode 270. In the synapse stack, analog memory characteristics may be implemented by forming the separate metal-oxide-based electrolyte 240 between the shared channel layer 210 and the shared gate dielectric 250.

The transistor stack and the synapse stack may share not only the shared channel layer 210 but also the shared gate dielectric 250. When the electrolyte 240 is positioned beneath the shared gate dielectric 250, the shared gate dielectric 250 may be disposed to form a step beneath the first gate electrode 260 and the second gate electrode 270.

In one embodiment, source and drain electrodes 220 and 230 partially overlapping the shared channel layer 210 are formed at both ends of the shared channel layer 210. The shared channel layer 210 may be stacked within a cavity formed between the source electrode 220 and the drain electrode 230. The shared channel layer 210 may be formed in a structure extending toward the lower inner sides of the facing source and drain electrodes 220 and 230. The shared channel layer 210 may include a metal oxide and may be formed of, for example, WO₃, TiO₂, IGZO, ITO, IZO, or IWO.

In one embodiment, the portion of the shared channel layer 210 that is located between the first gate electrode 260 and the second gate electrode 270 and does not overlap the gates may be manufactured to have a negative threshold voltage, based on an n-type transistor, in order to maintain a good current conduction state. Although only a top-gate structure, in which the gate electrodes are disposed at the uppermost position, is illustrated herein, the present disclosure is not limited thereto and may also be implemented in a bottom-gate structure in which the gate electrodes are disposed at the bottom.

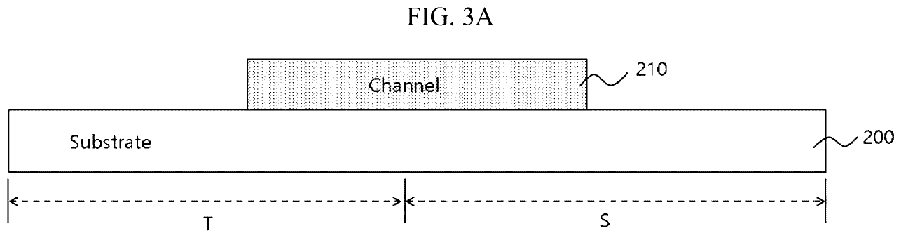

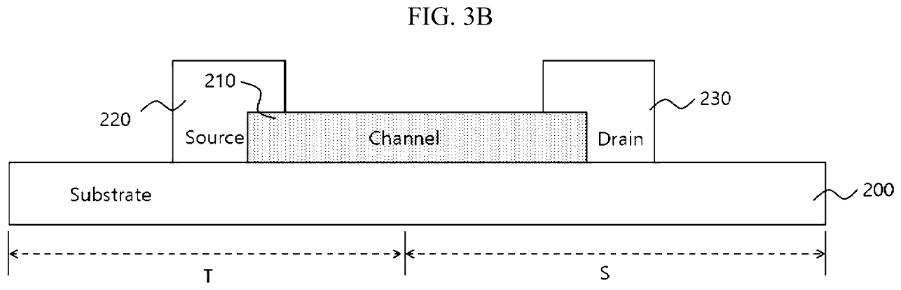

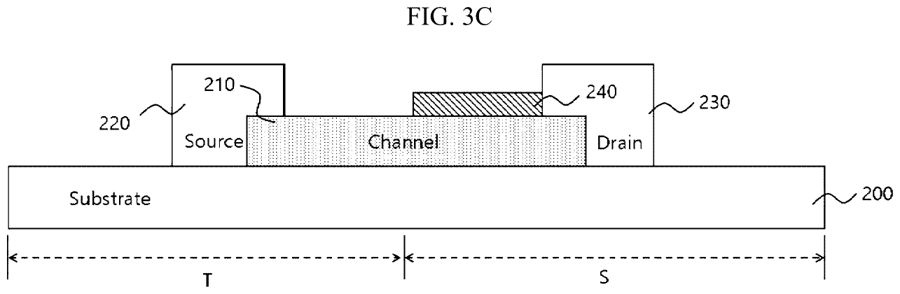

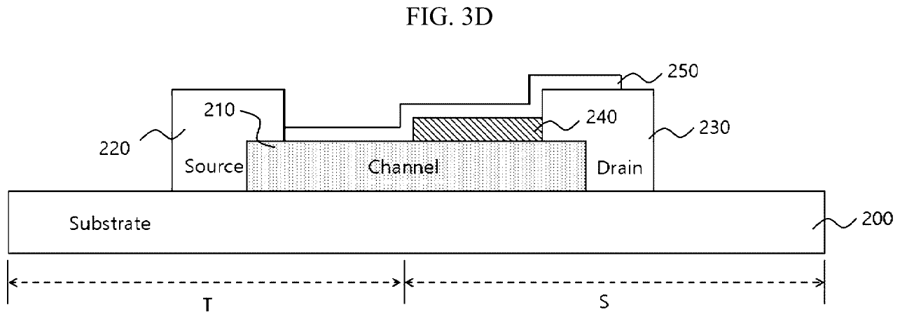

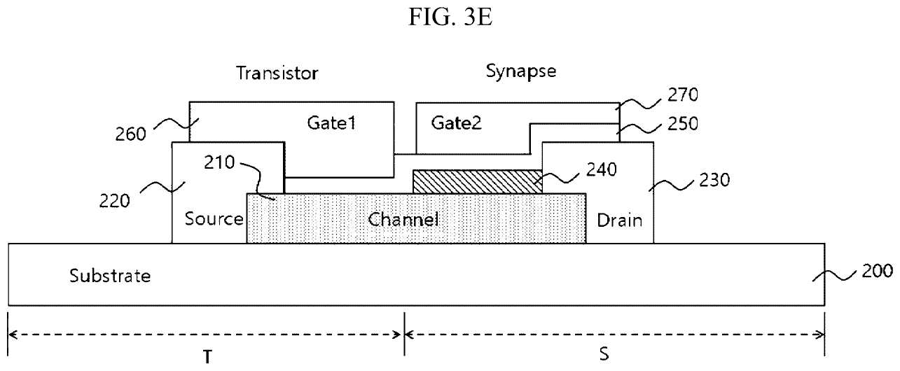

FIGS. 3A to 3E show sectional views illustrating a method of manufacturing a shared channel-based artificial intelligence neuromorphic device according to an example embodiment of the present disclosure.

Referring to FIG. 3A, a shared channel layer 210 is formed on an upper portion of a substrate 200. The substrate 200 may include silicon (Si) or silicon carbide (SiC), and the shared channel layer 210 may be formed of materials such as silicon (Si), gallium arsenide (GaAs), or graphene.

Referring to FIG. 3B, source and drain electrodes 220 and 230 partially overlapping both ends of the shared channel layer 210 are formed on the upper portion of the substrate 200. At this time, the source electrode 220 and the drain electrode 230 may be formed of a metallic material such as aluminum (Al), gold (Au), copper (Cu), or any one selected from combinations thereof.

Referring to FIG. 3C, an electrolyte 240 is formed on the shared channel layer 210 between the source electrode 220 and the drain electrode 230. At this time, the electrolyte 240 may be formed only in a synapse device region S. The electrolyte 240 may be formed only in the synapse device region S to perform charge storage and information transfer functions.

Referring to FIG. 3D, a shared gate dielectric 250 having a predetermined thickness is formed on the shared channel layer 210 including the electrolyte 240 and on the drain electrode 230. At this time, the shared gate dielectric 250 may be formed with a step due to the electrolyte 240 and the drain electrode 230. In one embodiment, the electrolyte 240 may be formed of a porous material such as silicon oxide (SiO₂) or silicon nitride (Si₃N₄), and specific compounds for ion storage may also be used. In addition, the shared gate dielectric 250 may be formed of silicon oxide (SiO₂), hafnium oxide (HfO₂), or silicon nitride (Si₃N₄).

Referring to FIG. 3E, a gate metal layer is formed over the entire upper surface including the shared gate dielectric 250. The gate metal layer may be formed of aluminum (Al), molybdenum (Mo), titanium (Ti), or the like. Thereafter, the gate metal layer is patterned to form a first gate electrode 260 in a transistor region T and a second gate electrode 270 in the synapse device region S, respectively. That is, in the transistor region T, a transistor stack composed of the first gate electrode 260 is formed, and in the synapse device region S, a synapse stack composed of the second gate electrode 270 is formed. The gate metal layer serves to control the flow of current in the channel by adjusting electrical signals. Different gate electrodes are formed in the transistor region T and the synapse device region S, allowing them to perform different functions while sharing the same channel, thereby enabling integrated operation.

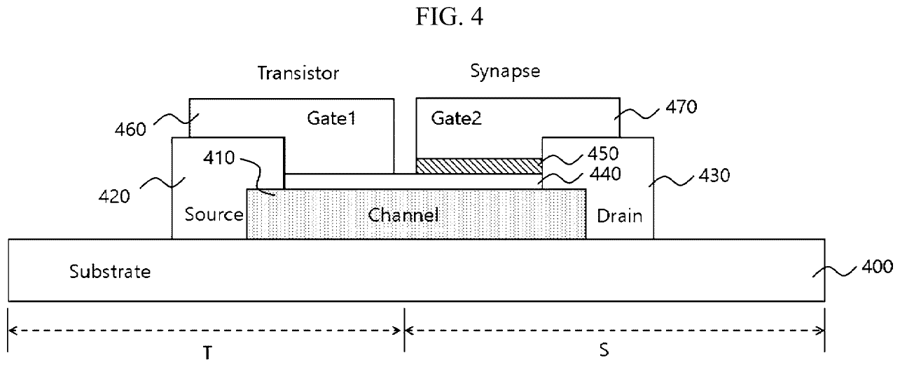

FIG. 4 is a sectional view illustrating a shared channel-based artificial intelligence neuromorphic device according to another example embodiment of the present disclosure, explaining a case in which the synapse device is an electrochemical random-access memory (ECRAM).

Referring to FIG. 4, a shared channel layer 410 is provided on an upper portion of a substrate 400, and source and drain electrodes 420 and 430 partially overlapping the shared channel layer 410 are provided on both ends of the shared channel layer 410. A transistor stack partially overlapping the source electrode 420 is provided in a transistor region T, and a synapse stack partially overlapping the drain electrode 430 is provided in a synapse device region S.

The transistor stack may include the shared channel layer 410, a shared gate dielectric 440, and a first gate electrode 460, while the synapse stack may include the shared channel layer 410, the shared gate dielectric 440, an ion reservoir 450, and a second gate electrode 470.

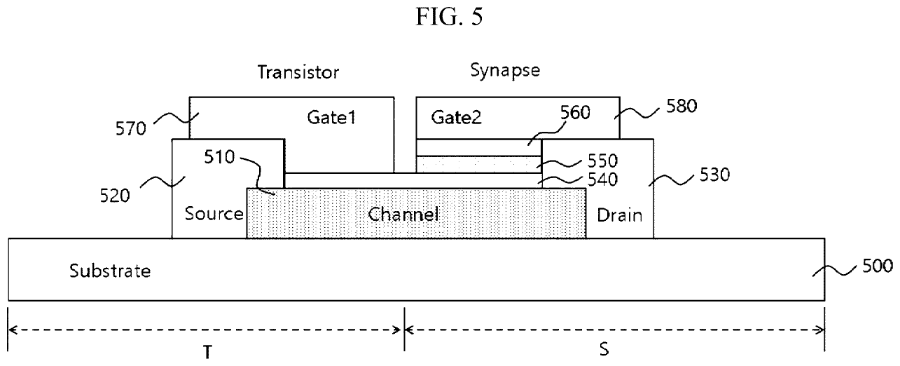

FIG. 5 is a sectional view illustrating a shared channel-based artificial intelligence neuromorphic device according to another example embodiment of the present disclosure, explaining a case in which a synapse device is a flash-based memory device.

Referring to FIG. 5, a shared channel layer 510 is provided on an upper portion of a substrate 500, and source and drain electrodes 520 and 530 partially overlapping the shared channel layer 510 are provided on both ends of the shared channel layer 510. A transistor stack partially overlapping the source electrode 520 is provided in a transistor region T, and a synapse stack partially overlapping the drain electrode 530 is provided in a synapse device region S.

The transistor stack may include the shared channel layer 510, a shared gate dielectric 540, and a first gate electrode 570, while the synapse stack may include the shared channel layer 510, the shared gate dielectric 540, a floating gate 550, an inter-poly dielectric or blocking oxide 560, and a second gate electrode 580. In this case, a charge trapping layer may be formed instead of the floating gate 550, or the floating gate 550 and the charge trapping layer may be stacked together.

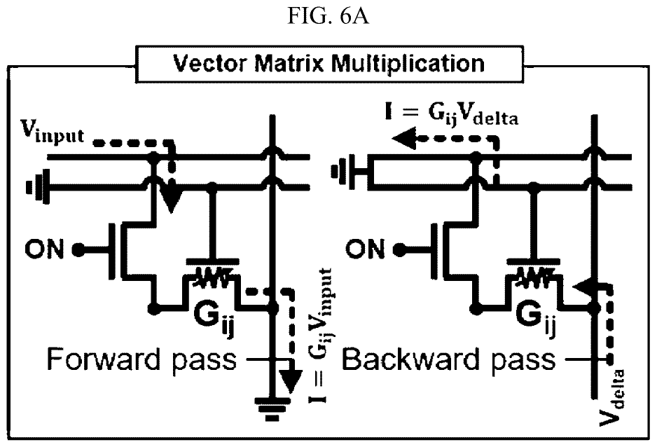

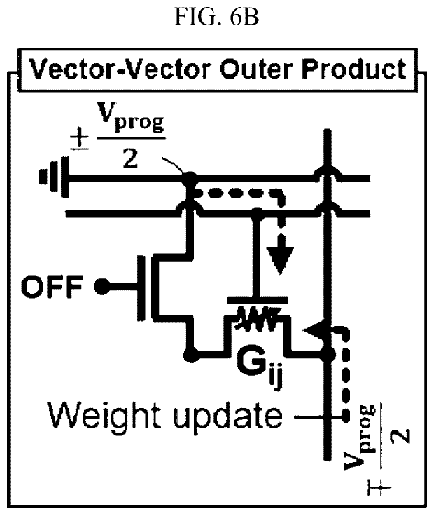

FIGS. 6A and 6B are diagrams for explaining an operating method of a shared channel-based artificial intelligence neuromorphic device according to an example embodiment of the present disclosure, illustrating an operation scheme for the operation of an artificial neural network in a unit-cell-based cross-point array.

First, referring to FIG. 6A, for vector-matrix multiplication, a first gate electrode may be turned on, and an input voltage Vᵢₙₚᵤₜ may be provided to a source electrode to perform a forward pass operation for inference. That is, when a transistor is turned on and the input voltage is applied in a row direction, a current flowing in a column direction may be read.

In addition, a backward pass operation for error calculation may be performed by turning on the first gate electrode and providing a delta voltage V_{delta} to a drain electrode. That is, when the transistor is turned on and the delta voltage is applied in the column direction, a current flowing in the row direction may be read.

Referring to FIG. 6B, for vector-vector outer product operation, the first gate electrode of the transistor may be turned off, and probabilistic voltage pulses of opposite polarities may be applied to the second gate electrode of the synapse device and the source electrode. That is, by turning off the transistor and applying probabilistic voltage pulses of opposite polarities in the row and column directions, a weight update may be performed. During the update, since the transistor connected to the drain of the synapse device is turned off, the voltage applied to the source is formed across the entire channel by the channel-boosting effect.

Therefore, it is possible to overcome the problem of degradation in device characteristics caused by a voltage drop that occurs in a conventional synapse device during the update, because the drain is grounded.

As described above, the present disclosure proposes a structure in which a transistor and an analog memory device are connected in series, in order to overcome performance degradation caused by a voltage drop that occurs when a conventional three-terminal analog memory device is updated using a half-bias update scheme. During the update, the transistor connected to the analog memory device is turned off, and a bias is formed across the entire channel by the channel-boosting effect, thereby enhancing the synaptic characteristics. In addition, by establishing a driving method for a unit-cell-based cross-point array, the present disclosure can contribute to achieving excellent learning accuracy in a hardware cross-point array that mimics an artificial neural network.

While example embodiments of the present disclosure have been described above, it will be understood by those skilled in the art that various modifications and changes may be made to the present disclosure without departing from the spirit and scope of the present disclosure as set forth in the claims that follow.

### National Research and Development Project Supporting the Present Disclosure

[Project ID] 2410000230
[Subproject ID] 00236568
[Name of department] Ministry of Trade, Industry and Energy
[Research Management Agency] Korea Evaluation Institute of Industrial Technology
[Research Project Name] Public-Private Joint Investment Semiconductor Advanced Workforce Development (R&D)
[Research Task Name] Development of High-Performance CMOS-Compatible ECRAM Devices for Implementation of High-Density Storage-Class Memory and Deep Learning Accelerators
[Performing Organization] Pohang University of Science and Technology (POSTECH) Industry-Academic Cooperation Foundation
[Research Period] 2024-01-01 to 2024-12-31
[Project ID] 2710006311
[Subproject ID] 00405960
[Name of department] Ministry of Science and ICT
[Research Management Agency] National Research Foundation of Korea
[Research Project Name] Next-Generation Intelligent Semiconductor Technology Development (R&D)
[Research Task Name] Development of Core Technology for Two-Terminal Variable Threshold Voltage Devices and Crossbar Arrays for High-Density Memory
[Performing Organization] Pohang University of Science and Technology (POSTECH) Industry-Academic Cooperation Foundation
[Research Period] 2024-03-01 to 2025-02-28

What is claimed is:

1. A shared channel-based artificial intelligence neuromorphic device, comprising:
a substrate;
a shared channel layer stacked on the substrate;
a shared gate dielectric stacked on the shared channel layer;
a transistor stack including a first gate electrode; and
a synapse stack including a second gate electrode,
wherein each of the transistor stack and the synapse stack includes at least a portion of the shared channel layer and at least a portion of the shared gate dielectric so that the shared channel layer and the shared gate dielectric are shared by the transistor stack and the synapse stack.

2. The shared channel-based artificial intelligence neuromorphic device according to claim 1, further comprising:
a source electrode at least partially overlapping one end of the shared channel layer; and
a drain electrode at least partially overlapping the other end of the shared channel layer.

3. The shared channel-based artificial intelligence neuromorphic device according to claim 2, wherein the shared channel layer is stacked within a cavity formed between the source electrode and the drain electrode.

4. The shared channel-based artificial intelligence neuromorphic device according to claim 2, wherein the shared channel layer extends toward lower inner sides facing each other from the source electrode and the drain electrode.

5. The shared channel-based artificial intelligence neuromorphic device according to claim 1, wherein, when the synapse stack is an electrochemical memory device, the synapse stack further comprises a charge storage layer disposed above or beneath the shared gate dielectric.

6. The shared channel-based artificial intelligence neuromorphic device according to claim 5, wherein, when the charge storage layer is positioned beneath the shared gate dielectric, the shared gate dielectric is disposed to form a step beneath the first and second gate electrodes.

7. The shared channel-based artificial intelligence neuromorphic device according to claim 5, wherein the charge storage layer is disposed above or beneath the shared gate dielectric to implement analog memory characteristics.

8. The shared channel-based artificial intelligence neuromorphic device according to claim 1, wherein, when the synapse stack is a flash-based memory device, a floating gate or a charge trapping layer is stacked on the shared gate dielectric, and an insulating layer is stacked on the floating gate or the charge trapping layer.

9. The shared channel-based artificial intelligence neuromorphic device according to claim 1, wherein the shared channel layer located between the first gate electrode and the second gate electrode is configured to have a negative threshold voltage.

10. The shared channel-based artificial intelligence neuromorphic device according to claim 2, wherein, for vector-matrix multiplication, the first gate electrode is turned on and an input voltage is applied to the source electrode to perform a forward pass operation for inference, and the first gate electrode is turned on and a delta voltage is applied to the drain electrode to perform a backward pass operation for error calculation.

11. The shared channel-based artificial intelligence neuromorphic device according to claim 2, wherein, for vector-vector outer product operation, the first gate electrode is turned off, and probabilistic voltage pulses of opposite polarities are applied to the second gate electrode and the source electrode.

12. A shared channel-based artificial intelligence neuromorphic device, comprising:
a cross-point array based on a resistive processing unit,
wherein the cross-point array comprises a unit cell composed of a transistor and a synapse device, and
wherein the unit cell is configured in a structure in which the transistor and the synapse device are connected in series.

13. The shared channel-based artificial intelligence neuromorphic device according to claim 12, wherein the transistor is composed of an n-type or p-type semiconductor,
wherein the transistor comprises a metal-oxide-semiconductor field-effect transistor (MOSFET) or an oxide semiconductor, and
wherein the synapse device comprises a three-terminal analog memory device.

14. The shared channel-based artificial intelligence neuromorphic device according to claim 12, wherein, for vector-matrix operation, the transistor is turned on, and a current generated by resistance of the synapse device is measured.

15. The shared channel-based artificial intelligence neuromorphic device according to claim 12, wherein, for weight updating, the transistor is turned off, and voltage pulses are applied to a gate electrode and a source electrode of the synapse device using a half-bias scheme.
